(19) United States
(12) Patent Application Publication
(10) Pub. No.: US 2026/0270588 A1
(43) Pub. Date: Sep. 10, 2026

(54) IMAGING DEVICE

(71) Applicant: SONY SEMICONDUCTOR SOLUTIONS CORPORATION, KANAGAWA (JP)

(72) Inventor: Yuta KUSHIDA, KANAGAWA (JP)

(21) Appl. No.: 18/871,924

(22) PCT Filed: Apr. 20, 2023
(86) PCT No.: PCT/JP2023/015793

§ 371 Date: Dec. 5, 2024

(30) Foreign Application Priority Data
Jun. 15, 2022 (JP) 2022-096658

(51) Int. Cl. H04N 25/77; H04N 25/13

(52) U.S. Cl. CPC H04N 25/766; H04N 25/134; H04N 25/771; H04N 25/778

(57) ABSTRACT

An imaging device according to an aspect of the present disclosure includes a plurality of first light receiving pixels and a plurality of second light receiving pixels. Each of the plurality of first light receiving pixels includes N-number of first photodiodes and a first floating diffusion, the first floating diffusion accumulating a charge transferred from each of the first photodiodes via a first wiring. Each of the plurality of second light receiving pixels includes M-number of second photodiodes (M<N) and a second floating diffusion, the second floating diffusion accumulating a charge transferred from each of the second photodiodes via a second wiring. Each of the plurality of second light receiving pixels includes a capacitance adjustment section adjusted to have conversion efficiency of each of the plurality of first light receiving pixels and conversion efficiency of each of the plurality of second light receiving pixels substantially equal to one another.

### TECHNICAL FIELD

The present disclosure relates to an imaging device that captures an image of a subject.

### BACKGROUND ART

An imaging device is, for example, provided with a plurality of light receiving pixels for generation of a captured image. An imaging device is known provided with light receiving pixels, each of the light receiving pixels including, for example, a plurality of photodiodes sharing a floating diffusion and the number of photodiodes included in each of the light receiving pixels being not identical between all the light receiving pixels (for example, see PTL 1).

### CITATION LIST

### Patent Literature

PTL 1: Japanese Unexamined Patent Application Publication No. 2015-91025

### SUMMARY OF THE INVENTION

Meanwhile, in a case where the number of photodiodes included in each of the light receiving pixels is not identical between all the light receiving pixels, an issue is in that a captured image to be obtained may be low in color reproducibility. Thus, it is desirable to provide an imaging device that allows high color reproducibility to be achieved.

An imaging device according to an aspect of the present disclosure includes a plurality of first light receiving pixels and a plurality of second light receiving pixels. Each of the plurality of first light receiving pixels includes N-number of first photodiodes and a first floating diffusion, the first floating diffusion accumulating a charge transferred from each of the first photodiodes via a first wiring. Each of the plurality of second light receiving pixels includes M-number of second photodiodes (M<N) and a second floating diffusion, the second floating diffusion accumulating a charge transferred from each of the second photodiodes via a second wiring. Each of the plurality of second light receiving pixels includes a capacitance adjustment section adjusted to have conversion efficiency of each of the plurality of first light receiving pixels and conversion efficiency of each of the plurality of second light receiving pixels substantially equal to one other.

In the imaging device according to an aspect of the present disclosure, the capacitance adjustment section is provided in each of the second light receiving pixels, the capacitance adjustment section adjusted to have conversion efficiency of each of the first light receiving pixels and conversion efficiency of each of the second light receiving pixels substantially equal to one other, the number of photodiodes being different from one another between the first light receiving pixels and the second light receiving pixels. With this, deterioration in image quality due to inconsistency in conversion efficiency is suppressed.

### BRIEF DESCRIPTION OF DRAWING

FIG. 1 is a diagram illustrating an example of a schematic configuration of an imaging device according to one embodiment of the present disclosure.

FIG. 2 is a diagram illustrating an example of a planar configuration of a pixel array illustrated in FIG. 1.

FIG. 3 is a diagram illustrating an example of a cross-sectional configuration of a light receiving pixel illustrated in FIG. 2.

FIG. 4 is a diagram illustrating an example of a circuit configuration of a pixel block illustrated in FIG. 2.

FIG. 5 is a diagram illustrating an example of a circuit configuration of a pixel block illustrated in FIG. 2.

FIG. 6 is a diagram illustrating a connection example between a plurality of the pixel blocks illustrated in FIGS. 4 and 5.

FIG. 7 is a block diagram illustrating a configuration example of a readout section illustrated in FIG. 1.

FIG. 8 is a diagram illustrating one configuration example of an image signal illustrated in FIG. 1.

FIG. 9 is a diagram illustrating an example of a planar configuration of a plurality of the pixel blocks illustrated in FIGS. 4 and 5.

FIG. 10 is a diagram illustrating a configuration example of wirings illustrated in FIG. 9.

FIG. 11 is a diagram describing capacitances of a plurality of the pixel blocks illustrated in FIGS. 4 and 5.

FIG. 12 is a diagram illustrating one modification example of the circuit configuration of the pixel block illustrated in FIG. 4.

FIG. 13 is a diagram illustrating an example of a planar configuration of a pixel array illustrated in FIGS. 5 and 12.

FIG. 14 is a diagram illustrating a configuration example of wirings illustrated in FIG. 13.

FIG. 15 is a diagram describing capacitances of a plurality of the pixel blocks illustrated in FIGS. 5 and 12.

FIG. 16 is a diagram illustrating one modification example of the circuit configuration of the pixel block illustrated in FIG. 12.

FIG. 17 is a diagram illustrating an example of a planar configuration of a pixel array illustrated in FIGS. 5 and 16.

FIG. 18 is a diagram illustrating a configuration example of wirings illustrated in FIG. 15.

FIG. 19 is a diagram describing capacitances of a plurality of the pixel blocks illustrated in FIGS. 5 and 16.

FIG. 20 is a diagram illustrating a configuration example of wirings obtained by combining the wirings illustrated in FIG. 10 and the wirings illustrated in FIG. 14.

FIG. 21 is a diagram describing capacitances of a plurality of pixel blocks having the configuration in FIG. 20.

FIG. 22 is a diagram illustrating one example of relation between output levels and optical shot noises.

FIG. 23 is an explanatory diagram illustrating examples of uses of the imaging device.

FIG. 24 is a block diagram depicting an example of schematic configuration of a vehicle control system.

FIG. 25 is a diagram of assistance in explaining an example of installation positions of an outside-vehicle information detecting section and an imaging section.

### MODES FOR CARRYING OUT THE INVENTION

Hereinafter, embodiments of the present disclosure will be described in detail with reference to the drawings. The following description is specific examples of the present disclosure, and thus the present disclosure is not limited to the following aspects. Note that the description will be given in the following order.
1. Embodiments
2. Method of Measuring Conversion Efficiency
3. Examples of Uses of Imaging Device
4. Application to Mobile Object

### 1. Embodiments

### [Configuration Example]

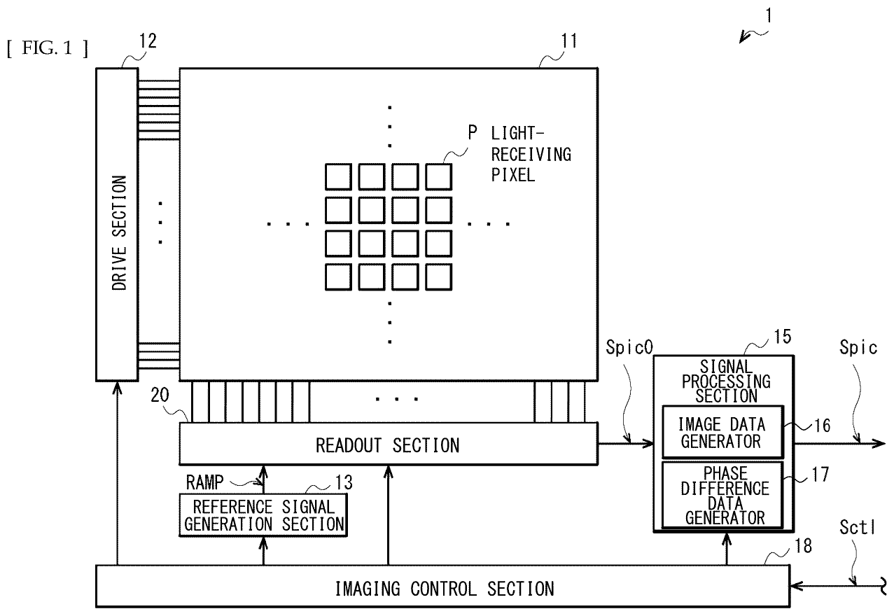

FIG. 1 illustrates an example of a schematic configuration of an imaging device 1 according to one embodiment of the present disclosure. The imaging device 1 includes a pixel array 11, a drive section 12, a reference signal generation section 13, a readout section 20, a signal processing section 15, and an imaging control section 18.

The pixel array 11 includes a plurality of light receiving pixels P arranged in a matrix. Each light receiving pixel P is configured to generate a signal SIG including a pixel voltage Vpix corresponding to the amount of received light.

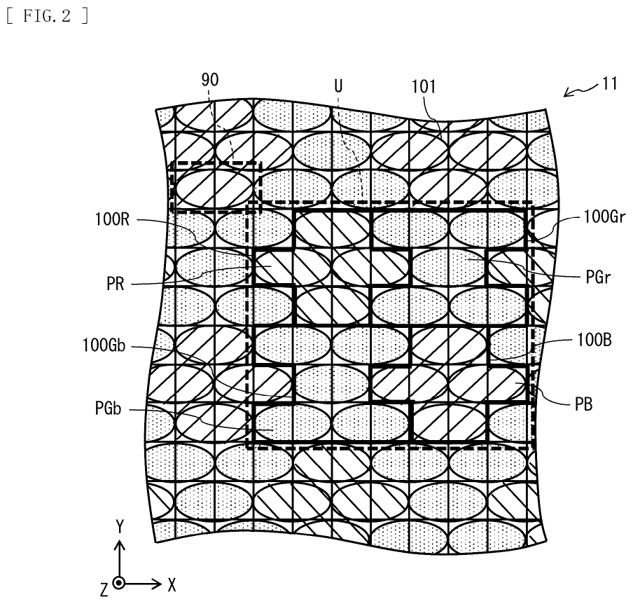

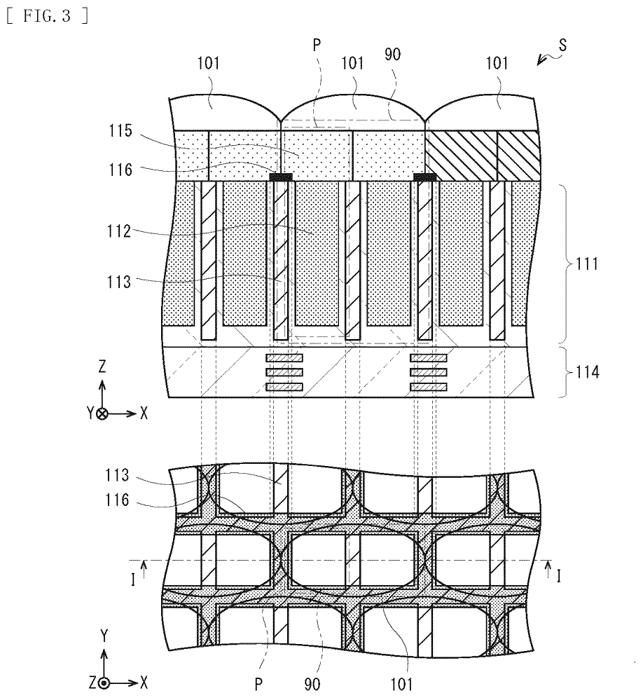

FIG. 2 illustrates one example of arrangement of the plurality of light receiving pixels P in the pixel array 11. FIG. 3 illustrates one example of a cross-sectional configuration of the pixel array 11. The pixel array 11 includes a plurality of pixel blocks 100 and a plurality of lenses 101.

The plurality of pixel blocks 100 includes pixel blocks 100R, 100Gr, 100Gb, and 100B. In the pixel array 11, the plurality of light receiving pixels P is arranged with four pixel blocks 100 (pixel blocks 100R, 100Gr, 100Gb, and 100B) required for color reproduction as a unit (unit U). Here, the light receiving pixels P each correspond to a specific example of a “first light receiving pixel” or a “second light receiving pixel” in the present disclosure. The pixel blocks 100Gr and 100Gb each correspond to a specific example of the “first light receiving pixel” in the present disclosure. The pixel blocks 100B and 100R each correspond to a specific example of the “second light receiving pixel” in the present disclosure.

The pixel block 100R includes eight light receiving pixels P (light receiving pixels PR) whose light incident surface is covered with a red (R) color filter 115. The pixel block 100Gr includes ten light receiving pixels P (light receiving pixels PGr) whose light incident surface is covered with a green (G) color filter 115. The pixel block 100Gb includes ten light receiving pixels P (light receiving pixels PGb) whose light incident surface is covered with a green (G) color filter 115. The pixel block 100B includes eight light receiving pixels P (light receiving pixels PB) whose light incident surface is covered with a blue (B) color filter 115. In FIG. 2, difference in color between the color filters is expressed with meshing.

The arrangement pattern of light receiving pixels PR in the pixel block 100R is the same as the arrangement pattern of light receiving pixels PB in the pixel block 100B. The arrangement pattern of light receiving pixels PGr in the pixel block 100Gr is the same as the arrangement pattern of light receiving pixels PGb in the pixel block 100Gb. In a unit U, for example, the pixel block 100Gr is disposed up right, the pixel block 100R is disposed up left, the pixel block 100B is disposed bottom right, and the pixel block 100Gb is disposed bottom left. As described above, the pixel blocks 100R, 100Gr, 100Gb, and 100B are arranged in a so-called Bayer array, with the pixel blocks 100 as units.

As illustrated in FIG. 3, the pixel array 11 includes a semiconductor substrate 111, semiconductor regions 112, an insulating layer 113, a multilayer wiring layer 114, the color filters 115, and a light shielding film 116. The semiconductor substrate 111 is a support substrate that the imaging device 1 is formed on and is a P-type semiconductor substrate (for example, Si substrate). The semiconductor regions 112 are semiconductor regions provided, in the substrate of the semiconductor substrate 111, at respective positions corresponding to the plurality of light receiving pixels P. In each semiconductor region 112, an N-type impurity is doped and thereby a photodiode PD is formed. The insulating layer 113 is provided, in the substrate of the semiconductor substrate 111, at a boundary between a plurality of light receiving pixels P provided side by side in the X-Y plane, and is, in this example, of deep trench isolation (DTI) configured using an oxide film or the like. The multilayer wiring layer 114 is provided on the semiconductor substrate 111, on a surface opposite to a light incident surface S of the pixel array 11, and includes a plurality of wiring layers and an inter-layer insulating film. Wirings in the multilayer wiring layer 114 are configured to connect a transistor (not illustrated) provided on a surface of the semiconductor substrate 111 and the drive section 12 and readout section 20, for example. The color filters 115 are wavelength selecting filters provided on the semiconductor substrate 111, on the light incident surface S of the pixel array 11. The light shielding film 116 is provided surrounding two light receiving pixels P provided side by side in the X direction (hereinafter, also referred to as pixel pair 90), in the light incident surface S of the pixel array 11.

The plurality of lenses 101 is so-called on-chip lenses and is provided on the color filters 115 on the light incident surface S of the pixel array 11. Each lens 101 is provided above two light receiving pixels P provided side by side in the X direction (pixel pair 90). Four lenses 101 are provided above the eight light receiving pixels P of the pixel block 100R. Five lenses 101 are provided above the ten light receiving pixels P of the pixel block 100Gr. Five lenses 101 are provided above the ten light receiving pixels P of the pixel block 100Gb. Four lenses 101 are provided above the eight light receiving pixels P of the pixel block 100B. The lenses 101 are provided side by side in the X direction and Y direction. The lenses 101 arranged in the Y direction are arranged being displaced by one light receiving pixel P each in the X direction. In other words, the pixel pairs 90 arranged in the Y direction are arranged being displaced by one light receiving pixel P each in the X direction.

With this configuration, between two light receiving pixels P in a pixel pair 90 corresponding to one lens 101, the images are displaced from each other. The imaging device 1 generates phase difference data DF on the basis of a so-called image plane phase difference detected with a plurality of the pixel pairs 90. For example, a camera including the imaging device 1 determines a defocusing amount on the basis of such phase difference data DF and causes the position of an imaging lens to be shifted on the basis of the defocusing amount. With this, the camera allows autofocus to be implemented.

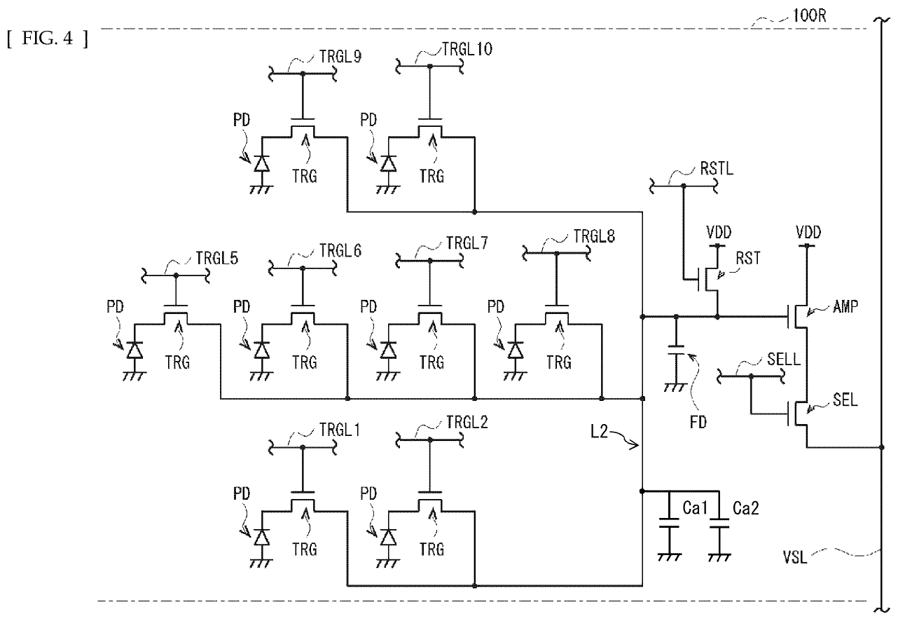

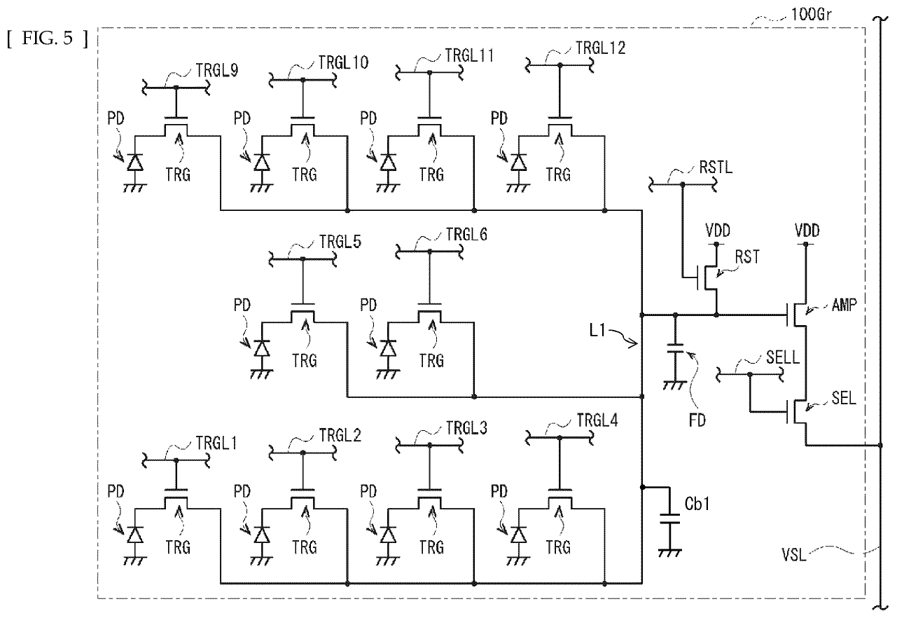

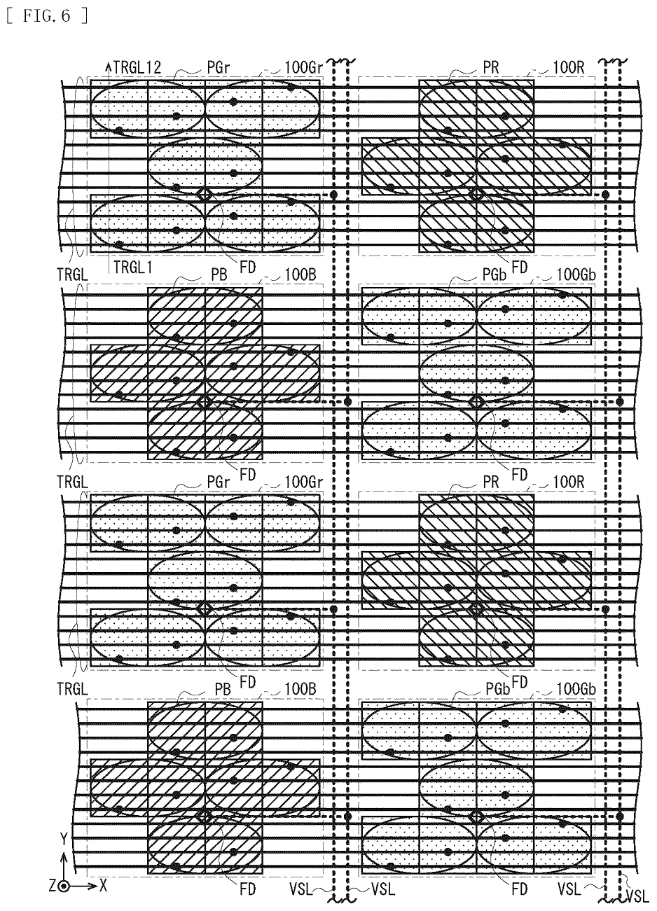

FIG. 4 illustrates a configuration example of the pixel block 100R. FIG. 5 illustrates a configuration example of the pixel block 100Gr. FIG. 6 illustrates an example of wiring for the pixel blocks 100R, 100Gr, 100Gb, and 100B. Note that, in FIG. 6, for convenience of the description, the plurality of pixel blocks 100 is illustrated away from one another.

The pixel array 11 includes a plurality of control lines TRGL, a plurality of control lines RSTL, a plurality of control lines SELL, and a plurality of signal lines VSL. Each control line TRGL extends in the X direction (lateral direction in FIGS. 4 to 6) and has one end connected to the drive section 12. The drive section 12 supplies a control signal STRG to the control line TRGL. Each control line RSTL extends in the X direction and has one end connected to the drive section 12. The drive section 12 supplies a control signal SRST to the control line RSTL. Each control line SELL extends in the X direction and has one end connected to the drive section 12. The drive section 12 supplies a control signal SSEL to the control line SELL. Each signal line VSL extends in the Y direction (vertical direction in FIGS. 4 to 6) and has one end connected to the readout section 20. The signal line VSL transmits a signal SIG generated by a light receiving pixel P to the readout section 20.

The pixel block 100B (FIG. 4) includes eight photodiodes PD, eight transistors TRG, one floating diffusion FD, and three transistors (transistors RST, AMP, and SEL). One pair of a photodiode PD and a transistor TRG corresponds to a light receiving pixel PR. In this example, the transistors TRG, RST, AMP, and SEL are N-type metal oxide semiconductor (MOS) transistors.

Each photodiode PD is a photoelectric conversion element that generates charges in an amount corresponding to the amount of received light and accumulates therein the generated charges. Each photodiode PD has an anode grounded and a cathode connected to a source of the corresponding transistor TRG. The photodiode PD of the pixel block 100B corresponds to a specific example of a “second photodiode” in the present disclosure.

Each transistor TRG has a gate connected to a control line TRGL, the source connected to the cathode of the corresponding photodiode PD, and a drain connected to the floating diffusion FD. The gates of the eight transistors TRG are connected to respective different control lines TRGL out of eight control lines TRGL (in this example, control lines TRGL1, TRGL2, and TRGL5 to TRGL10).

The floating diffusion FD is configured to accumulate charges transferred from each photodiode PD via the corresponding transistor TRG and a wiring L2 to be described later. The floating diffusion FD is configured, for example, using a diffusion layer formed on a surface of the semiconductor substrate 111. In FIG. 4, a symbol of capacitor is used to denote the floating diffusion FD.

The transistor RST has a gate connected to a control line RSTL, a drain supplied with a power supply voltage VDD, and a source connected to the floating diffusion FD. The transistor AMP has a gate connected to the floating diffusion FD, a drain supplied with a power supply voltage VDDH, and a source connected to a drain of the transistor SEL. The transistor SEL has a gate connected to a control line SELL, the drain connected to the source of the transistor AMP, and a source connected to a signal line VSL.

With this configuration, in each light receiving pixel P, for example, the transistors TRG and RST are turned on on the basis of control signals STRG and SRST and thereby charges accumulated in the photodiode PD are swept out. Then, these transistors TRG and RST are turned off, and thereby an exposure period T is caused to be started and charges in an amount corresponding to the amount of received light are accumulated in the photodiode PD. After expiration of the exposure period T, the light receiving pixel P then outputs a signal SIG including a reset voltage Vreset and a pixel voltage Vpix to the signal line VSL. Specifically, first, the transistor SEL is turned on on the basis of a control signal SSEL, and thereby the light receiving pixel P is electrically connected to the signal line VSL. With this, the transistor AMP is connected to a constant current source 21 (to be described later) of the readout section 20 and operates as a so-called source follower. Then, as described later, in a P-phase (Pre-charge phase) period TP after the voltage of the floating diffusion FD having been reset by turning on the transistor RST, the light receiving pixel P outputs, as the reset voltage Vreset, a voltage corresponding to a voltage of the floating diffusion FD at that time. Furthermore, in a D-phase (Data phase) period TD after charges having been transferred from the photodiode PD to the floating diffusion FD by turning on the transistor TRG, the light receiving pixel P outputs, as the pixel voltage Vpix, a voltage corresponding to a voltage of the floating diffusion FD at that time. The difference voltage between the pixel voltage Vpix and the reset voltage Vreset corresponds to the amount of received light of the light receiving pixel P in the exposure period T. As described above, the light receiving pixel P is configured to output the signal SIG including these reset voltage Vreset and pixel voltage Vpix to the signal line VSL.

The pixel block 100Gr (FIG. 5) includes ten photodiodes PD, ten transistors TRG, one floating diffusion FD, and three transistors (transistors RST, AMP, and SEL). One pair of a photodiode PD and a transistor TRG corresponds to a light receiving pixel PGr. Gates of the ten transistors TRG are connected to respective different control lines TRGL out of ten control lines TRGL (in this example, control lines TRGL1 to TRGL6 and TRGL9 to TRGL12). The photodiode PD of the pixel block 100Gr corresponds to a specific example of a “first photodiode” in the present disclosure.

As illustrated in FIG. 6, pixel blocks 100Gr and 100R arranged in the X direction belonging to the same row are each connected to a plurality of control lines TRGL out of the same twelve control lines TRGL (control lines TRGL1 to TRGL12). In this example, the control lines TRGL1 to TRGL12 are arranged in this order from the bottom to top in FIG. 6. The pixel block 100Gr is connected to ten control lines TRGL (control lines TRGL1 to TRGL6 and TRGL9 to TRGL12) out of the twelve control lines TRGL (control lines TRGL1 to TRGL12). The pixel block 100R is connected to eight control lines TRGL (control lines TRGL1, TRGL2, and TRGL5 to TRGL10) out of the twelve control lines TRGL (control lines TRGL1 to TRGL12).

Furthermore, although not illustrated, the pixel blocks 100Gr and 100R arranged in the X direction belonging to the same row are connected to one control line RSTL and one control line SELL.

Furthermore, as illustrated in FIG. 6, pixel blocks 100Gr arranged in the Y direction belonging to the same column are connected to one signal line VSL. Similarly, pixel blocks 100R arranged in the Y direction belonging to the same column are connected to one signal line VSL.

The pixel block 100B includes, similarly to the pixel block 100R (FIG. 4), eight photodiodes PD, eight transistors TRG, one floating diffusion FD, and three transistors (transistors RST, AMP, and SEL). One pair of a photodiode PD and a transistor TRG corresponds to a light receiving pixel PB. Gates of the eight transistors TRG are connected to respective different control lines TRGL out of eight control lines TRGL. The photodiode PD of the pixel block 100B corresponds to a specific example of the “second photodiode” in the present disclosure.

The pixel block 100Gb includes, similarly to the pixel block 100Gr (FIG. 5), ten photodiodes PD, ten transistors TRG, one floating diffusion FD, and three transistors (transistors RST, AMP, and SEL). One pair of a photodiode PD and a transistor TRG corresponds to a light receiving pixel PGb. Gates of the ten transistors TRG are connected to respective different control lines TRGL out of ten control lines TRGL. The photodiode PD of the pixel block 100Gb corresponds to a specific example of the “first photodiode” in the present disclosure.

As illustrated in FIG. 6, pixel blocks 100B and 100Gb arranged in the X direction belonging to the same row are each connected to a plurality of control lines TRGL out of the same twelve control lines TRGL. Furthermore, although not illustrated, the pixel blocks 100B and 100Gb arranged in the X direction belonging to the same row are connected to one control line RSTL and one control line SELL. Furthermore, as illustrated in FIG. 6, pixel blocks 100B arranged in the Y direction belonging to the same column are connected to one signal line VSL. Similarly, pixel blocks 100Gb arranged in the Y direction belonging to the same column are connected to one signal line VSL.

The drive section 12 (FIG. 1) is configured to drive the plurality of light receiving pixels P in the pixel array 11 on the basis of indication from the imaging control section 18. Specifically, the drive section 12 supplies respective control signals STRG to the plurality of control lines TRGL in the pixel array 11, supplies respective control signals SRST to the plurality of control lines RSTL, and supplies respective control signals SSEL to the plurality of control lines SELL, and thereby drives the plurality of light receiving pixels P in the pixel array 11.

The reference signal generation section 13 is configured to generate a reference signal RAMP on the basis of indication from the imaging control section 18. The reference signal RAMP has a so-called ramp waveform that the voltage level gradually changes over time in a period (P-phase period TP and D-phase period TD) for the readout section 20 to perform AD conversion. The reference signal generation section 13 supplies such a reference signal RAMP to the readout section 20.

The readout section 20 is configured to perform AD conversion on the basis of a signal SIG supplied from the pixel array 11 via the signal lines VSL to generate an image signal Spic0, on the basis of indication from the imaging control section 18.

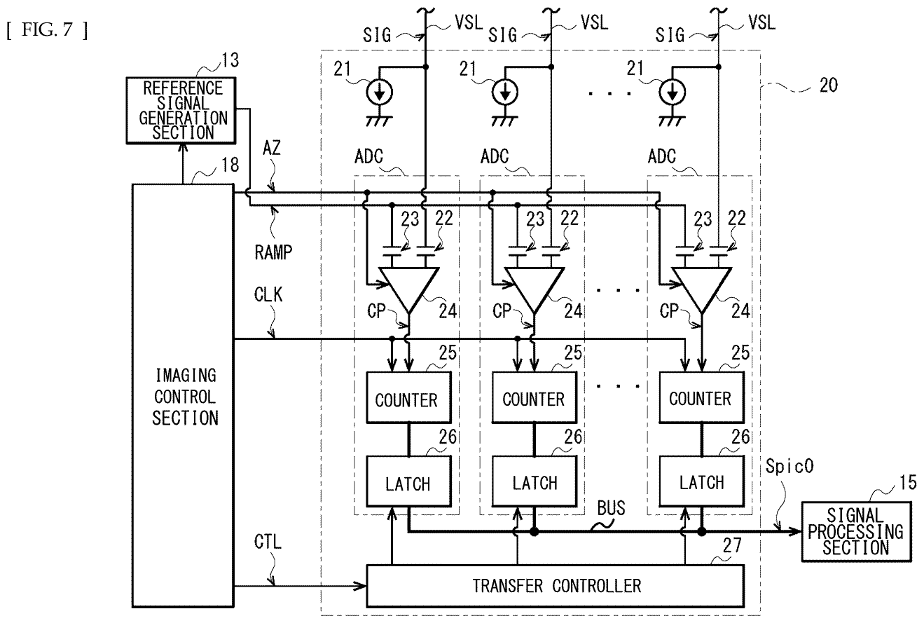

FIG. 7 illustrates one configuration example of the readout section 20. Note that FIG. 7 also illustrates, in addition to the readout section 20, the reference signal generation section 13, the signal processing section 15, and the imaging control section 18. The readout section 20 includes a plurality of constant current sources 21, a plurality of analog-to-digital (AD) converters ADC, and a transfer controller 27. One constant current source 21 and one AD converter ADC are connected to one signal line VSL.

Each constant current source 21 is configured to supply a predetermined current to the corresponding signal line VSL. Each constant current source 21 has one end connected to the corresponding signal line VSL and another end grounded.

Each AD converter ADC is configured to perform AD conversion on the basis of a signal SIG in the corresponding signal line VSL. The AD converter ADC includes capacitors 22 and 23, a comparator circuit 24, a counter 25, and a latch 26.

The capacitor 22 has one end connected to the signal line VSL and another end connected to the comparator circuit 24. The capacitor 22 is supplied with a signal SIG via the signal line VSL. The capacitor 23 has one end connected to the reference signal generation section 13 and another end connected to the comparator circuit 24. The capacitor 23 is supplied with a reference signal RAMP supplied from the reference signal generation section 13.

The comparator circuit 24 is configured to perform, on the basis of the signal SIG supplied from the light receiving pixel P via the signal line VSL and the capacitor 22 and the reference signal RAMP supplied from the reference signal generation section 13 via the capacitor 23, comparison operation to generate a signal CP. The comparator circuit 24 sets, on the basis of a control signal AZ supplied from the imaging control section 18, voltages for the capacitors 22 and 23 to set an operating point. Thereafter, the comparator circuit 24 performs, in the P-phase period TP, comparison operation of comparing a reset voltage Vreset included in the signal SIG with the voltage of the reference signal RAMP, and performs, in the D-phase period TD, comparison operation of comparing a pixel voltage Vpix included in the signal SIG with the voltage of the reference signal RAMP.

The counter 25 is configured to perform counting operation of counting a pulse of a clock signal CLK supplied from the imaging control section 18 on the basis of the signal CP supplied from the comparator circuit 24. Specifically, the counter 25 counts, in the P-phase period TP, the pulse of the clock signal CLK until transition of the signal CP to generate a count value CNTP, and outputs the count value CNTP as a digital code having a plurality of bits. Furthermore, the counter 25 counts, in the D-phase period TD, the pulse of the clock signal CLK until transition of the signal CP to generate a count value CNTD, and outputs the count value CNTD as a digital code having a plurality of bits.

The latch 26 is configured to temporary store the digital code supplied from the counter 25 and output, on the basis of indication from the transfer controller 27, the digital code to a bus wiring BUS.

The transfer controller 27 is configured to perform, on the basis of a control signal CTL supplied from the imaging control section 18, control of the plurality of AD converters ADC for the latches 26 of the plurality of AD converters ADC to output digital codes sequentially to the bus wiring BUS. With use of the bus wiring BUS, the readout section 20 sequentially transfers, to the signal processing section 15, the plurality of digital codes supplied from the plurality of AD converters ADC as the image signal Spic0.

The signal processing section 15 (FIG. 1) is configured to perform a predetermined signal processing to generate an image signal Spic, on the basis of the image signals Spic0 and indication from the imaging control section 18. The signal processing section 15 includes an image data generator 16 and a phase difference data generator 17. The image data generator 16 is configured to perform, on the basis of the image signals Spic0, a predetermined image processing to generate image data DP indicating a captured image. The phase difference data generator 17 is configured to perform, on the basis of the image signals Spic0, a predetermined image processing to generate phase difference data DF indicating an image plane phase difference. The signal processing section 15 generates the image signal Spic including the image data DP and the phase difference data DF.

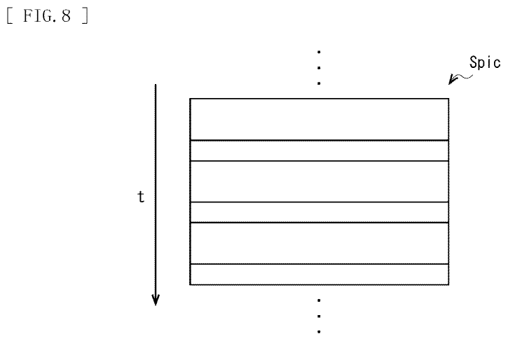

FIG. 8 illustrates one example of the image signal Spic. For example, the signal processing section 15 generates the image signal Spic by alternately disposing pieces of the image data DP related to a plurality of rows of light receiving pixels P and pieces of the phase difference data DF related to the plurality of rows of light receiving pixels P. Then, the signal processing section 15 outputs such an image signal Spic.

The imaging control section 18 is configured to supply a control signal to the drive section 12, the reference signal generation section 13, the readout section 20, and the signal processing section 15 and control operation in these circuits to control operation of the imaging device 1. The imaging control section 18 is supplied with a control signal Sctl from outside. The imaging control section 18 controls operation of the imaging device 1 on the basis of the control signal Sctl.

Next, capacitance of each light receiving pixel P will be described.

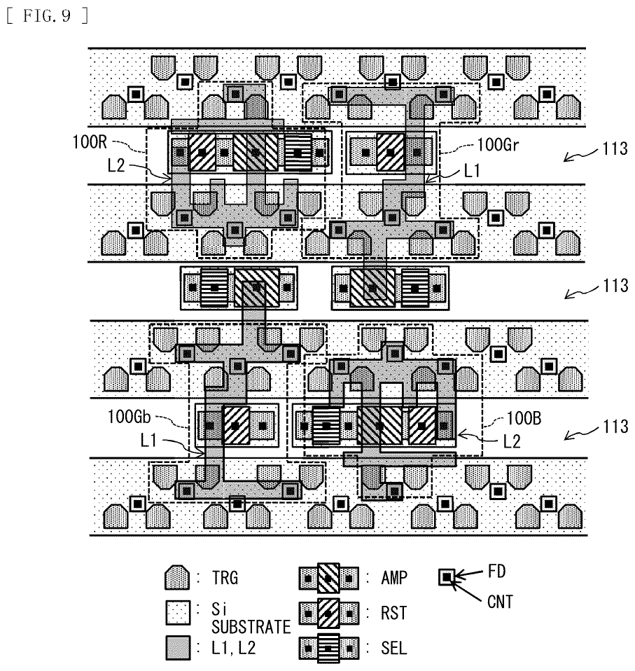

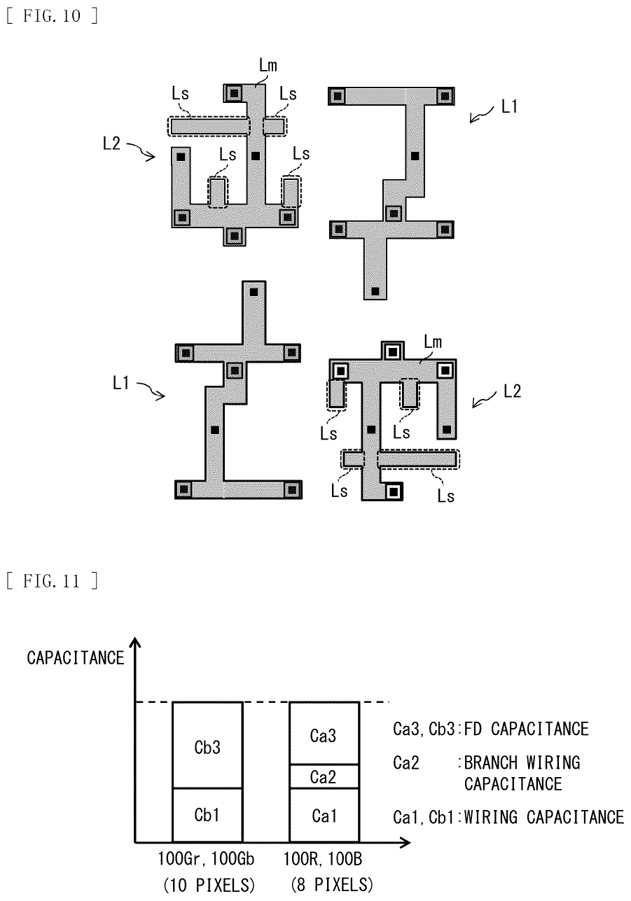

FIG. 9 illustrates an example of a planar configuration of the plurality of pixel blocks 100. FIG. 10 illustrates wirings L1 and L2 illustrated in FIG. 9 extracted. As illustrated in FIG. 9, the transistors TRG, AMP, RST, and SEL are formed on the semiconductor substrate 111 (Si substrate). The insulating layer 113 is provided between the transistors TRG and the transistors AMP, RST, and SEL.

In each of the pixel blocks 100R and 100B, as illustrated in FIGS. 4, 9, and 10, the wiring L2 connecting the drain of each of the transistors TRG and the floating diffusion FD is provided. In each of the pixel blocks 100Gr and 100Gb, as illustrated in FIGS. 5, 9, and 10, the wiring LI connecting the drain of each of the transistors TRG and the floating diffusion FD is provided. Each of the wirings L1 and L2 is electrically connected to the floating diffusion FD via a contact CNT. Furthermore, each of the wirings L1 and L2 is electrically connected to the gate of the transistor AMP and the source of the transistor RST, via the contact CNT.

Each wiring L1 corresponds to a specific example of a “first wiring” in the present disclosure. The floating diffusion FD of each of the pixel blocks 100Gr and 100Gb corresponds to a specific example of a “first floating diffusion” in the present disclosure. The floating diffusion FD of each of the pixel blocks 100R and 100B corresponds to a specific example of a “second floating diffusion” in the present disclosure.

Each wiring L2 includes a main wiring Lm and one or a plurality of branch wirings Ls. The main wiring Lm is connected to the drain of each transistor TRG, the gate of each of the floating diffusion FD and the transistor AMP, and the source of the transistor RST. Each of the one or the plurality of branch wirings Ls has one end coupled to the main wiring Lm and another end electrically open. FIG. 10 illustrates a case where four branch wirings Ls are coupled to the main wiring Lm. Note that a branch wiring similar to the branch wirings Ls may be coupled to each wiring L1. The main wiring Lm corresponds to a specific example of a “second wiring” in the present disclosure. The branch wirings Ls each correspond to a specific example of a “branch wiring” in the present disclosure.

FIG. 11 illustrates one example of capacitances of the pixel blocks 100R, 100Gr, 100Gb, and 100B. The capacitance of each of the pixel blocks 100Gr and 100Gb is a capacitance obtained by adding a capacitance (wiring capacitance Cb1) of the wiring L1 and a capacitance (FD capacitance Cb3) of the floating diffusion FD together. Meanwhile, the capacitance of each of the pixel blocks 100R and 100B is a capacitance obtained by adding a capacitance (wiring capacitance Cal) of the main wiring Lm, capacitances (branch wiring capacitances Ca2) of the branch wirings Ls, and a capacitance (FD capacitance Ca3) of the floating diffusion FD together.

The capacitances of the branch wirings Ls are adjusted to have conversion efficiency of each of the pixel blocks 100Gr and 100Gb conversion efficiency of each of the pixel blocks 100R and 100B substantially equal to one another. In other words, the branch wirings Ls each correspond to a specific example of a “capacitance adjustment section” in the present disclosure. As a result, the capacitances of the respective pixel blocks 100R, 100Gr, 100Gb, and 100B are substantially equal to one another.

### [Operation]

Next, operation of the imaging device 1 will be described.

The drive section 12 sequentially drives the plurality of light receiving pixels P in the pixel array 11 on the basis of indication from the imaging control section 18. The reference signal generation section 13 generates a reference signal RAMP on the basis of indication from the imaging control section 18. Each light receiving pixel P outputs, in the P-phase period TP, a reset voltage Vreset as a signal SIG, and outputs, in the D-phase period TD, a pixel voltage Vpix corresponding to the amount of received light as a signal SIG. The readout section 20 generates an image signal Spic0 on the basis of the signal SIG supplied from the pixel array 11 via the signal line VSL and indication from the imaging control section 18. In the signal processing section 15, the image data generator 16 performs a predetermined image processing to generate image data DP indicating a captured image, on the basis of the image signal Spic0. Furthermore, the phase difference data generator 17 performs a predetermined image processing to generate phase difference data DF indicating an image plane phase difference, on the basis of the image signal Spic0. Then, the signal processing section 15 generates an image signal Spic including the image data DP and the phase difference data DF. The imaging control section 18 supplies a control signal to the drive section 12, the reference signal generation section 13, the readout section 20, and the signal processing section 15 and control operation in these circuits to control operation of the imaging device 1.

### [Effects]

Next, effects of the imaging device 1 will be described.

In the present embodiment, the branch wirings Ls are provided whose capacitances are adjusted to have conversion efficiency of each of the pixel blocks 100Gr and 100Gb and conversion efficiency of each of the pixel blocks 100R and 100B substantially equal to one another. With this, deterioration in image quality due to inconsistency in conversion efficiency (capacitance) is suppressed. As a result, high color reproducibility is possible to be achieved.

### 2. Modification Example

### [Modification Example A]

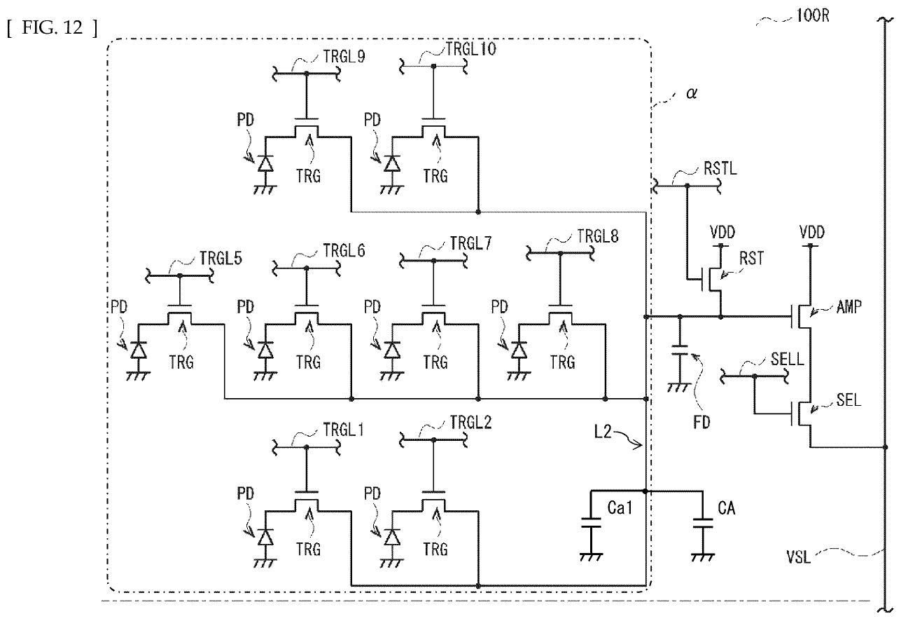

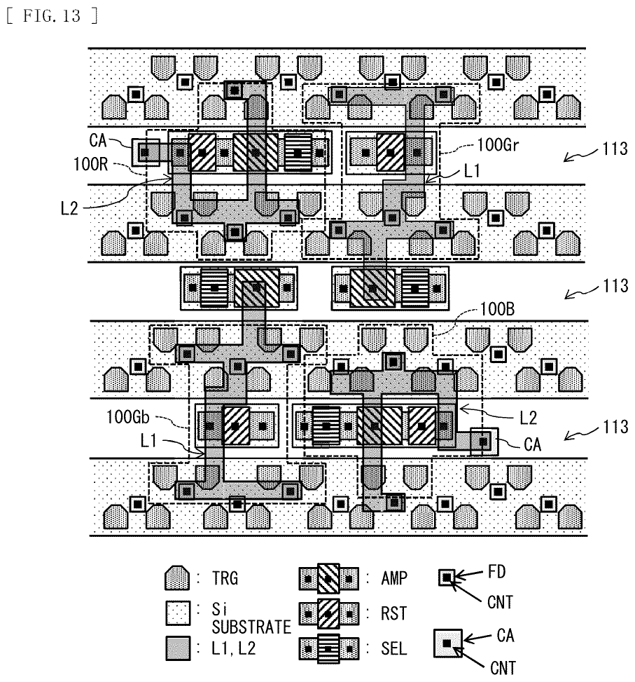

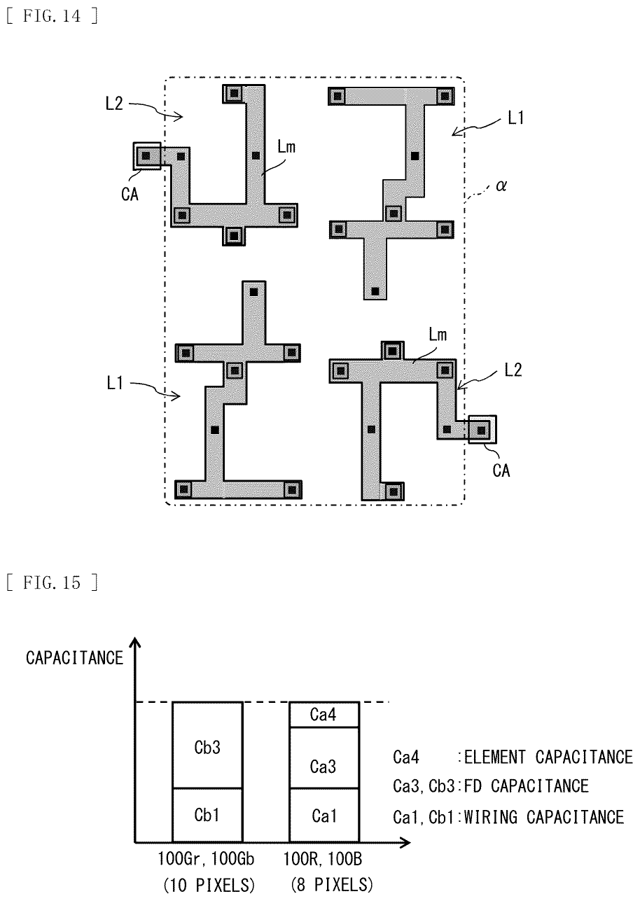

In the embodiment described above, each of the pixel blocks 100R and 100B may include a capacitor CA, instead of the branch wirings Ls, as illustrated in FIGS. 12, 13, and 14, for example. The capacitor CA corresponds to a specific example of a “capacitor” in the present disclosure. The capacitor CA is configured, for example, using a diffusion layer formed on a surface of the semiconductor substrate 111. The capacitor CA is coupled to the main wiring Lm, as illustrated in FIGS. 12 and 14, for example. In each of the pixel blocks 100R and 100B, the capacitor CA is disposed around a region α where a plurality of photodiodes PD is arrayed, as illustrated in FIGS. 12, 13, and 14, for example.

FIG. 15 illustrates one example of capacitances of the pixel blocks 100R, 100Gr, 100Gb, and 100B. The capacitance of each of the pixel blocks 100Gr and 100Gb is a capacitance obtained by adding a capacitance (wiring capacitance Cb1) of the wiring L1 and a capacitance (FD capacitance Cb3) of the floating diffusion FD together. Meanwhile, the capacitance of each of the pixel blocks 100R and 100B is a capacitance obtained by adding a capacitance (wiring capacitance Cal) of the wiring L2, a capacitance (FD capacitance Ca3) of the floating diffusion FD, and a capacitance (element capacitance Ca4) of the capacitor CA together.

The capacitance of the capacitor CA is adjusted to have conversion efficiency of each of the pixel blocks 100R and 100B and conversion efficiency of each of the pixel blocks 100Gr and 100Gb substantially equal to one another. In other words, the capacitor CA corresponds to a specific example of the “capacitance adjustment section” in the present disclosure. As a result, the capacitance of each of the pixel blocks 100Gr and 100Gb is substantially equal to the capacitance of each of the pixel blocks 100R and 100B.

In the present modification example, the capacitor CA is provided whose capacitance is adjusted to have conversion efficiency of each of the pixel blocks 100R and 100B and conversion efficiency of each of the pixel blocks 100Gr and 100Gb substantially equal to one another. With this, deterioration in image quality due to inconsistency in conversion efficiency (capacitance) is suppressed. As a result, high color reproducibility is possible to be achieved.

Furthermore, in the present modification example, the capacitances of the pixel blocks 100R, 100Gr, 100Gb, and 100B are adjusted with the capacitor CA. With this, issues possible to be caused in a case where capacitance adjustment is made with a wiring capacitance is unlikely to be caused, the issues including a limited wiring layout due to refining and an increase in the number of wiring layers.

### [Modification Example B]

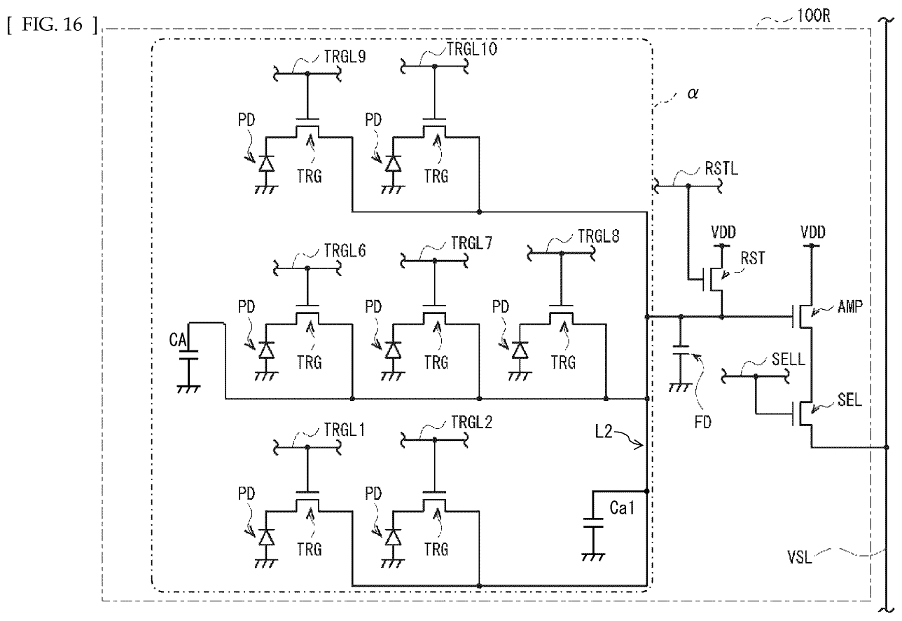

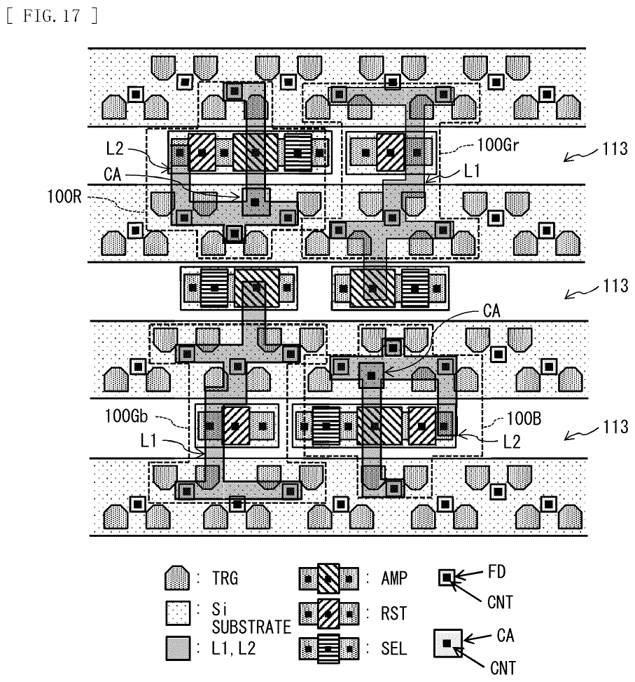

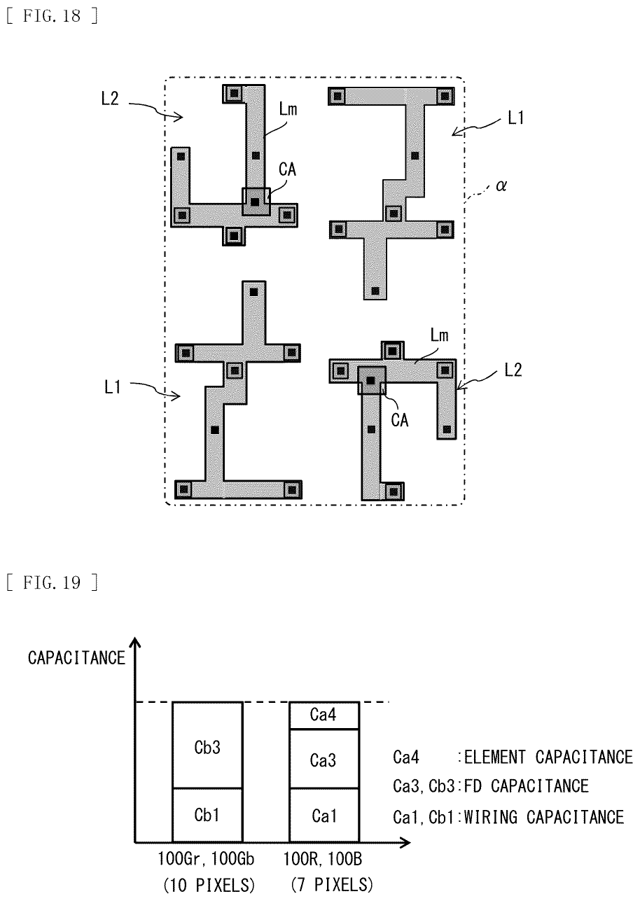

In each of the pixel blocks 100R and 100B according to Modification Example A described above, the capacitor CA may be disposed within a region α where a plurality of photodiodes PD is arrayed, as illustrated in FIGS. 16, 17, and 18, for example.

FIG. 19 illustrates one example of capacitances of the pixel blocks 100R, 100Gr, 100Gb, and 100B. The capacitance of each of the pixel blocks 100Gr and 100Gb is a capacitance obtained by adding a capacitance (wiring capacitance Cb1) of the wiring L1 and a capacitance (FD capacitance Cb3) of the floating diffusion FD together. Meanwhile, the capacitance of each of the pixel blocks 100R and 100B is a capacitance obtained by adding a capacitance (wiring capacitance Ca1) of the wiring L2, a capacitance (FD capacitance Ca3) of the floating diffusion FD, and a capacitance (element capacitance Ca4) of the capacitor CA together.

As described above, in Modification Example A, eight pairs of photodiodes PD and transistors TRG are provided in each of the pixel blocks 100R and 100B. Meanwhile, in the present modification example, one pair out of the eight pairs of photodiodes PD and transistors TRG is omitted in each of the pixel blocks 100R and 100B, and a region (blank region) caused thereby is provided with the capacitor CA disposed. With this, in the present modification example, the capacitor CA is possible to be formed in a size large enough. Therefore, with the capacitor CA, capacitance adjustment is easy to have conversion efficiency of each of the pixel blocks 100R and 100B and, conversion efficiency of each of the pixel blocks 100Gr and 100Gb substantially equal to one another.

### [Modification Example C]

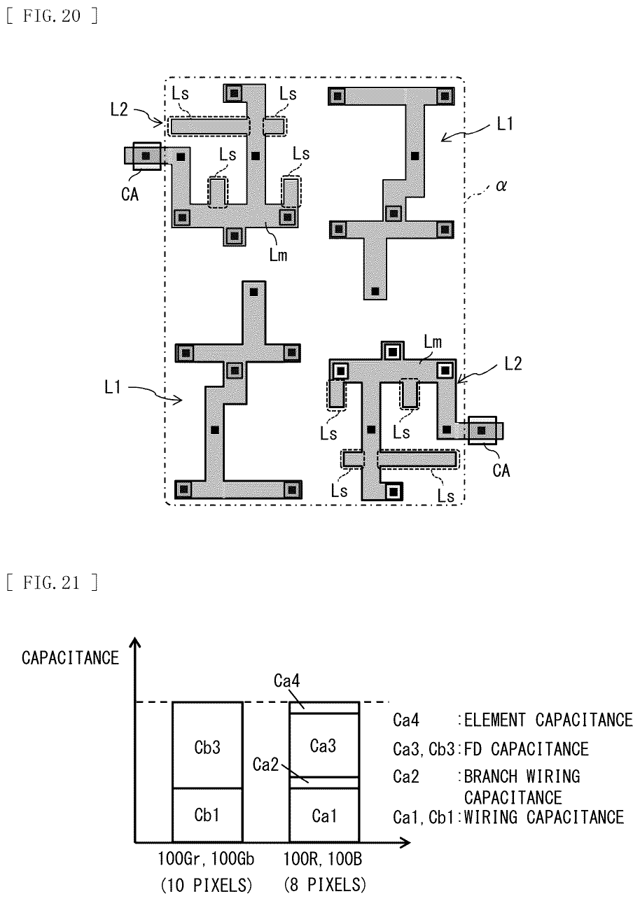

In the embodiment described above, each of the pixel blocks 100R and 100B may include, for capacitance adjustment, one or a plurality of branch wirings Ls and a capacitor CA as illustrated in FIG. 20, for example.

FIG. 21 illustrates one example of capacitances of the pixel blocks 100R, 100Gr, 100Gb, and 100B. The capacitance of each of the pixel blocks 100Gr and 100Gb is a capacitance obtained by adding a capacitance (wiring capacitance Cb1) of the wiring L1 and a capacitance (FD capacitance Cb3) of the floating diffusion FD together. Meanwhile, the capacitance of each of the pixel blocks 100R and 100B is a capacitance obtained by adding a capacitance (wiring capacitance Cal) of the main wiring Lm, capacitances (branch wiring capacitances Ca2) of the branch wirings LS, a capacitance (FD capacitance Ca3) of the floating diffusion FD, and a capacitance (element capacitance Ca4) of the capacitor CA together.

As described above, in the present modification example, for capacitance adjustment, the one or the plurality of branch wirings Ls and the capacitor CA are provided. This allows capacitance adjustment to be made without causing issues including a limited wiring layout due to refining and an increase in the number of wiring layers.

### [Modification Example D]

In the embodiment described above and the modification examples thereof, each of the pixel blocks 100R and 100B includes eight light receiving pixels P and each of the pixel blocks 100Gr and 100Gb includes ten light receiving pixels P. In the embodiment described above and the modification examples thereof, however, it is sufficient that the number M of light receiving pixels P included in each of the pixel blocks 100Gr and 100Gb is smaller than the number N of light receiving pixels P included in each of the pixel blocks 100R and 100B. Furthermore, in the embodiment described above and the modification examples thereof, the arrangement of the pixel blocks 100R, 100Gr, 100Gb, and 100B may be different from that in a Bayer array described above.

### 2. Method of Measuring Conversion Efficiency

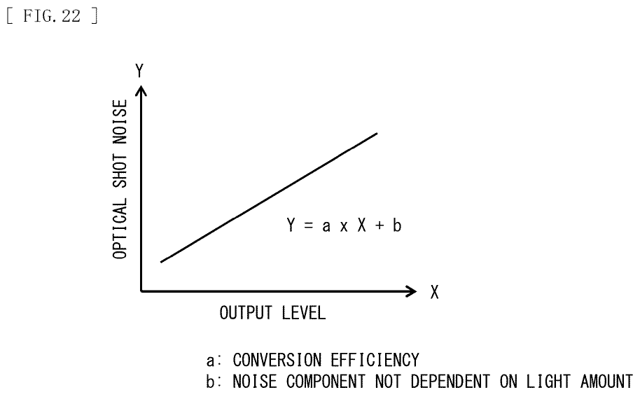

Meanwhile, conversion efficiencies of the light receiving pixels P are determined by the capacitance of the floating diffusion FD and the gain of the transistor AMP that operates as a source follower. The gain of the transistor AMP is determined by a gate capacitance of the transistor AMP. In the present embodiment, the respective conversion efficiencies of the light receiving pixels P are substantially equal to one another, and thus the variation of the capacitance of the floating diffusion FD is possible to be seen by the movement of the conversion efficiencies of the light receiving pixels P. Examples of the method of measuring conversion efficiency of a light receiving pixel P includes a measurement method of determining the dependence of an optical shot noise (noise component of light quantity dependent) depending on an output level (a level of a signal SIG of a signal line VSL) of the light receiving pixel P. A result obtained by measurement of such a measurement method is expressed by a graph illustrated in FIG. 22, for example. This graph is expressed as Y=a×X+b. Here, a represents conversion efficiency of a light receiving pixel P. b represents a noise component of light quantity independent.

### 3. Examples of Uses of Imaging Device

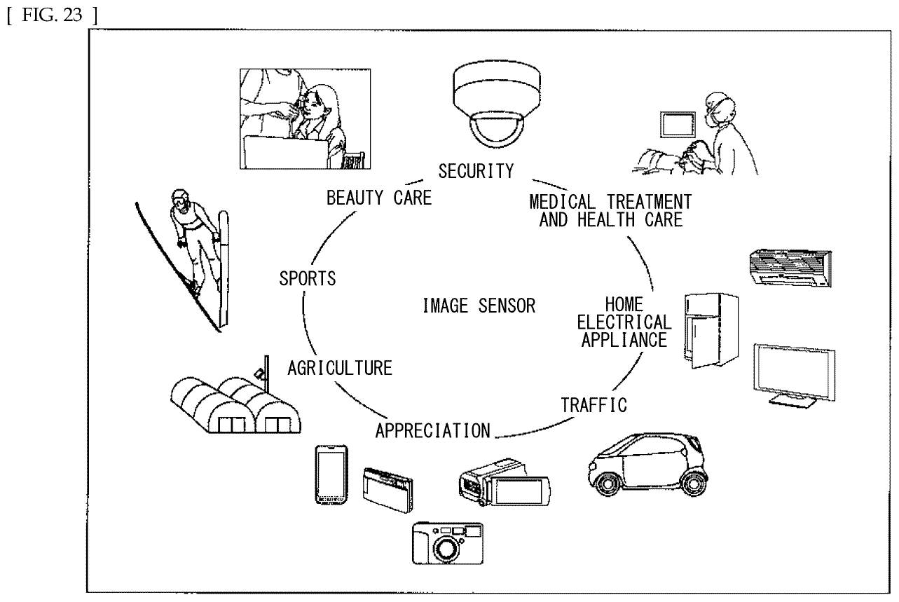

FIG. 23 illustrates examples of uses of the imaging device 1 according to the embodiment described above and the modification examples thereof. The imaging device 1 described above is possible to be used for various cases of sensing light such as visible light, infrared light, ultraviolet light, or X-ray as follows, for example.
Devices that capture images used for viewing, such as digital cameras or mobile devices with camera functions
Devices used for traffic for safe driving such as automatic stop, recognition of the condition of driver, etc., such as: in-vehicle sensors that capture an image of an environment in front of, at the rear of, and around automobile, the interior of the automobile, etc. ; surveillance cameras that monitor traveling vehicles or road; or distance measurement sensors that measure the distance between vehicles, etc.
Devices used in home appliances such as TVs, refrigerators, or air conditioners to capture an image of user's gesture and perform operations according to the gesture
Devices used for medical and healthcare, such as endoscopes or devices that perform angiography by receiving infrared light
Devices used for security, such as surveillance cameras for crime prevention or cameras for personal authentication
Devices used for beauty, such as skin measuring devices that capture an image of the skin or microscopes that capture the image of the scalp
Devices used for sports such as action cameras or wearable cameras for sporting use, etc.
Devices used for agriculture, such as cameras for monitoring the condition of fields and crops

### 4. Application to Mobile Object

The technique according to the present disclosure (present technique) can be applied to various products. For example, the technique according to the present disclosure may be implemented as a device mounted on any type of mobile objects such as vehicles, electric vehicles, hybrid electric vehicles, motorcycles, bicycles, personal mobilities, airplanes, drones, ships, or robots.

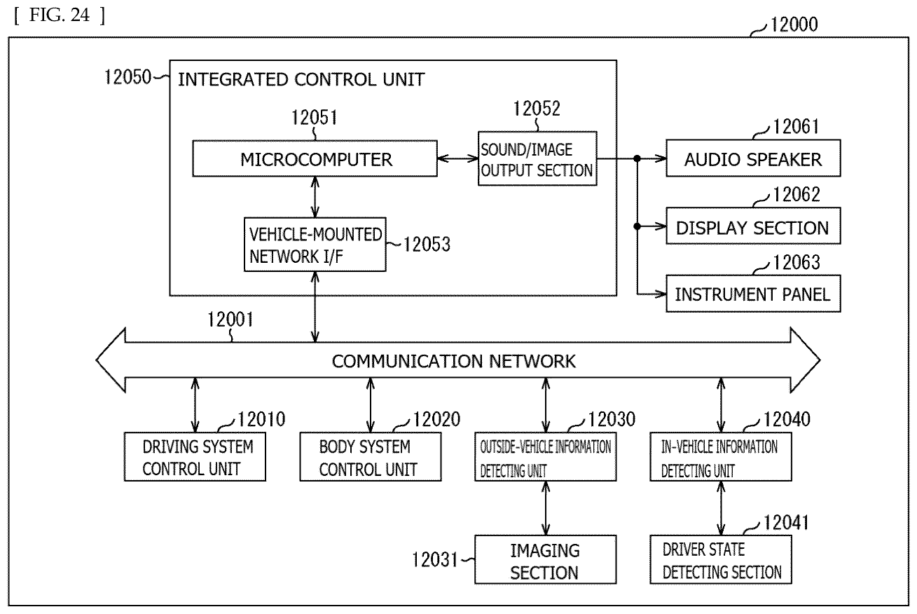

FIG. 24 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 24, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 24, an audio speaker 12061, a display section 12062, and an instrument panel 12063 are illustrated as the output device. The display section 12062 may, for example, include at least one of an on-board display and a head-up display.

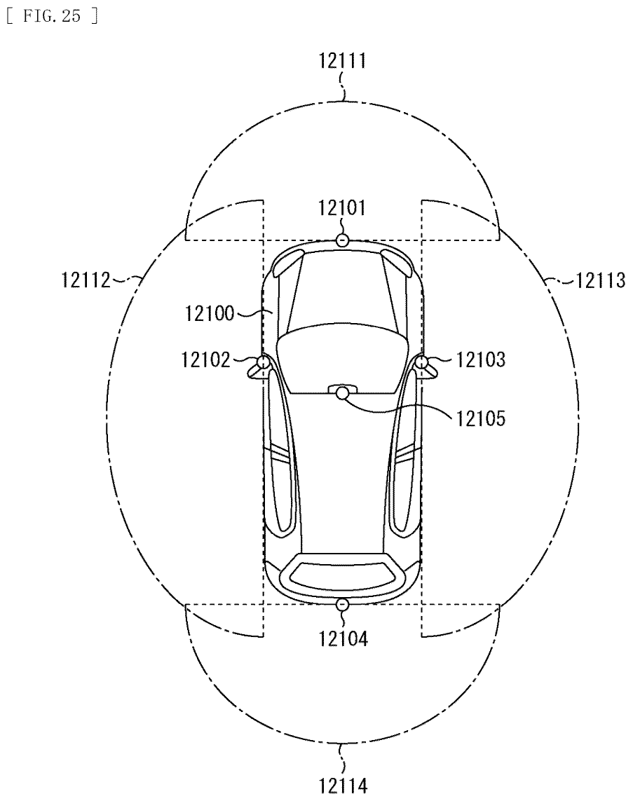

FIG. 25 is a diagram depicting an example of the installation position of the imaging section 12031.

In FIG. 25, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 25 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

One example of the vehicle control system to which the technique according to the present disclosure may be applied has been described above. The technique according to the present disclosure may be applied to the imaging section 12031 in the configuration described above. An imaging device mounted on a vehicle allows image quality of a captured image to be enhanced. As a result, the vehicle control system 12000 is possible to implement, with high accuracy, a function of collision avoidance or shock mitigation for the vehicle, a function of following driving based on distance between vehicles, a function of vehicle speed maintaining driving, a function of warning of collision of the vehicle, a function of warning of lane departure of the vehicle, and the like.

While the present technique has been described above providing the embodiments, the modification examples, and specific examples of application thereof, the present technique is not limited to the embodiments or the like described above, and various modifications are possible.

For example, the arrangement of the pixel blocks in the pixel array and the arrangement of the light receiving pixels P in each of the pixel blocks are not limited to the arrangements described in the embodiments or the like described above, and various arrangements are possible.

Note that the effects described in this specification is only examples, which are not limited, and another effect may be present.

Note that the present technique is possible to have a configuration as below. The present technique having such a configuration as below allows image quality of a captured image to be enhanced.

(1)

An imaging device including:
a plurality of first light receiving pixels; and
a plurality of second light receiving pixels, in which
each of the plurality of first light receiving pixels includes N-number of first photodiodes and a first floating diffusion, the first floating diffusion accumulating a charge transferred from each of the first photodiodes via a first wiring,
each of the plurality of second light receiving pixels includes M-number of second photodiodes (M <N) and a second floating diffusion, the second floating diffusion accumulating a charge transferred from each of the second photodiodes via a second wiring, and
each of the plurality of second light receiving pixels includes a capacitance adjustment section adjusted to have conversion efficiency of each of the plurality of first light receiving pixels and conversion efficiency of each of the plurality of second light receiving pixels substantially equal to one another.
   (2)

The imaging device according to (1), in which the capacitance adjustment section includes one or a plurality of branch wirings each having one end coupled to the second wiring and another end electrically open.

(3)

The imaging device according to (1) or (2), in which the capacitance adjustment section includes a capacitor coupled to the second wiring.

(4)

The imaging device according to (3), in which the capacitor, in each of the plurality of second light receiving pixels, is disposed around a region where the second photodiodes are arrayed.

(5)

The imaging device according to (3), in which the capacitor, in each of the plurality of second light receiving pixels, is disposed within a region where the second photodiodes are arrayed.

The present application claims the benefit of Japanese Priority Patent Application JP2022-096658 filed with the Japan Patent Office on Jun. 15, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. An imaging device comprising:
a plurality of first light receiving pixels; and
a plurality of second light receiving pixels, wherein
each of the plurality of first light receiving pixels includes N-number of first photodiodes and a first floating diffusion, the first floating diffusion accumulating a charge transferred from each of the first photodiodes via a first wiring,
each of the plurality of second light receiving pixels includes M-number of second photodiodes (M<N) and a second floating diffusion, the second floating diffusion accumulating a charge transferred from each of the second photodiodes via a second wiring, and
each of the plurality of second light receiving pixels includes a capacitance adjustment section adjusted to have conversion efficiency of each of the plurality of first light receiving pixels and conversion efficiency of each of the plurality of second light receiving pixels substantially equal to one another.

2. The imaging device according to claim 1, wherein the capacitance adjustment section includes one or a plurality of branch wirings each having one end coupled to the second wiring and another end electrically open.

3. The imaging device according to claim 1, wherein the capacitance adjustment section includes a capacitor coupled to the second wiring.

4. The imaging device according to claim 3, wherein the capacitor, in each of the plurality of second light receiving pixels, is disposed around a region where the second photodiodes are arrayed.

5. The imaging device according to claim 3, wherein the capacitor, in each of the plurality of second light receiving pixels, is disposed within a region where the second photodiodes are arrayed.
